(19) United States
(12) Patent Application Publication
(10) Pub. No.: US 2026/0156955 A1
(43) Pub. Date: Jun. 4, 2026

(54) IMAGE SENSOR

(71) Applicant: Samsung Electronics Co., Ltd., Suwon-si (KR)

(72) Inventors: HYOUN-JEE HA, Suwon-si (KR); JINMYOUNG LEE, Suwon-si (KR)

(21) Appl. No.: 19/399,801

(22) Filed: Nov. 25, 2025

(30) Foreign Application Priority Data
Dec. 2, 2024 (KR) 10-2024-0176531

(51) Int. Cl. H10F 39/00; H04N 25/77; H10F 39/18

(52) U.S. Cl. CPC H10F 39/80377; H10F 39/014; H10F 39/182; H04N 25/77

(57) ABSTRACT

An image sensor according to an embodiment of the present disclosure includes a substrate, a selection transistor positioned on a surface of the substrate, and an amplifying transistor connected to the selection transistor, wherein a channel material of the selection transistor and a channel material of the amplifying transistor are different materials, and the channel material of the amplifying transistor includes a two-dimensional material.

### CROSS-REFERENCE TO RELATED APPLICATION

This application claims priority to and the benefit of Korean Patent Application No. 10-2024-0176531 filed at the Korean Intellectual Property Office on Dec. 2, 2024, the entire contents of which are incorporated herein by reference.

### BACKGROUND

### Field

The present disclosure relates to an image sensor.

### Description of the Related Art

An image sensor is a semiconductor device that converts an optical image into an electrical signal. The image sensor may be classified as a charge coupled device (CCD) type and a complementary metal oxide semiconductor (CMOS) type. The CMOS image sensor is abbreviated as CIS (CMOS image sensor). The CIS includes a plurality of pixels arranged in two dimensions. Each of the pixels includes a photodiode (PD). The photodiode serves to convert incident light into an electrical signal.

Recently, an image sensor has been proposed in which a semiconductor wafer having a plurality of pixels and a semiconductor wafer including a transistor that reads signal charges in a charge accumulator are stacked.

### SUMMARY

The present disclosure provides an image sensor with improved noise.

An image sensor according to an embodiment of the present disclosure includes a substrate, a selection transistor on a surface of the substrate, and an amplifying transistor connected to the selection transistor, wherein a channel material of the selection transistor and a channel material of the amplifying transistor are different materials, and the channel material of the amplifying transistor includes a two-dimensional material.

An image sensor according to another embodiment includes a first substrate including a first surface and a second surface facing the first surface and including a photodiode region, a transmission transistor, and a floating diffusion positioned on the first surface of the first substrate, a second substrate including a first surface and a second surface facing the first surface, and a plurality of transistors positioned on the first surface of the second substrate, each transistor of the plurality of transistors being connected to the transmission transistor, wherein the plurality of transistors positioned on the first surface of the second substrate includes a reset transistor configured to initialize the floating diffusion, an amplifying transistor having a gate connected to the floating diffusion, and a selection transistor connected to one end of the amplifying transistor, and wherein a channel material of the amplifying transistor is different from a channel material of the reset transistor and a channel material of the selection transistor.

An image sensor according to another embodiment includes a substrate including a photodiode region, a transmission transistor connected to the photodiode region, a floating diffusion connected to the transmission transistor, an amplifying transistor having a gate connected to the floating diffusion, a reset transistor configured to initialize the floating diffusion, and a selection transistor connected to one end of the amplifying transistor, wherein a channel material of the amplifying transistor is different from a channel material of the reset transistor and a channel material of the selection transistor, and the channel material of the amplifying transistor includes a two-dimensional material.

According to embodiments, an image sensor with improved noise is provided.

### BRIEF DESCRIPTION OF THE DRAWINGS

FIG. 1 is a block diagram illustrating an image sensor according to an embodiment.

FIG. 2 is a circuit diagram of a single pixel included in an image sensor according to embodiments of the present disclosure.

FIG. 3 is a top plan view showing an image sensor according to embodiments of the present disclosure.

FIG. 4 illustrates a part of a cross-section of a single pixel PX of an image sensor according to the present embodiment.

FIG. 5 is an enlarged view of an amplifying transistor of FIG. 4.

FIG. 6 illustrates a cross-section in the dotted line direction—i.e., a cross-section in a second direction DR2—of the amplifying transistor of FIG. 5.

FIGS. 7 to 15 illustrate a method for manufacturing the amplifying transistor according to the present embodiment.

FIGS. 16 to 18 illustrate a channel doping process of an amplifying transistor according to another embodiment.

FIG. 19 illustrates the same region as FIG. 5 for another embodiment.

FIG. 20 illustrates the same region as FIG. 5 for another embodiment.

FIG. 21 illustrates the same region as FIG. 5 for another embodiment.

FIG. 22 illustrates the same region as FIG. 4 for another embodiment.

FIG. 23 illustrates the same region as FIG. 22 for another embodiment.

### DETAILED DESCRIPTION

The present disclosure will be described in detail hereinafter with reference to the accompanying drawings, in which embodiments of the present disclosure are shown. As those skilled in the art would realize, the described embodiments may be modified in various different ways, all without departing from the spirit or scope of the present disclosure.

The drawings and description are to be regarded as illustrative in nature and not restrictive, and like reference numerals designate like elements throughout the specification and drawings.

Further, because sizes and thicknesses of components shown in the accompanying drawings may be arbitrarily given to facilitate understanding and ease of description, the disclosure is not limited to the illustrated sizes and thicknesses. In the drawings, the thicknesses of layers, films, panels, regions, etc., are exaggerated for clarity. In the drawings, to facilitate understanding and ease of description, the thicknesses of some layers and regions may be exaggerated.

It should be understood that when an element such as a layer, film, region, or substrate is referred to as being “connected to” or “on” another element, it can be directly connected to or on the other element or intervening elements may also be present. Further, when an element is referred to as being “on” or “above” a reference element, it may be positioned above or below the reference element, and it may not necessarily be referred to as being positioned “on” or “above” it in a direction opposite to gravity.

In addition, unless explicitly described to the contrary, the words “include” and variations such as “including” and “comprise” and variations such as “comprises” and “comprising” should be understood to imply the inclusion of stated elements but not the exclusion of any other elements.

In addition, the phrase “on a plane” means a view from a position above the object (e.g., from the top), and the phrase “in a cross-section” means a view of a cross-section of the object which is vertically cut from the side.

Items described in the singular herein may be provided in plural, as can be seen, for example, in the drawings. Thus, the description of a single item that is provided in plural should be understood to be applicable to the remaining plurality of items unless context indicates otherwise.

As used herein, the term “two-dimensional material” includes sheet-like materials with a thickness of a few nanometers or less, for example a few atoms thick - in a direction perpendicular to the plane of the sheet. In examples, electrons can move freely within the two dimensional plane.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

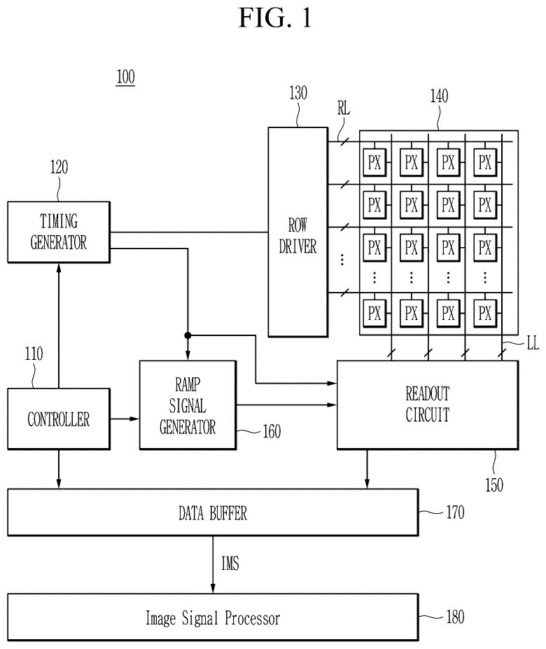

FIG. 1 is a block diagram illustrating an image sensor according to an embodiment.

Referring to FIG. 1, an image sensor 100 according to an embodiment may include a controller 110, a timing generator 120, a row driver 130, a pixel array 140, a readout circuit 150, a ramp signal generator 160, a data buffer 170, and an image signal processor 180. In an embodiment, the image signal processor 180 may be positioned outside the image sensor 100.

The image sensor 100 may generate an image signal by converting light received from the outside into an electrical signal. The image signal may be provided to the image signal processor 180.

The image sensor 100 may be mounted on an electronic device having an image or light sensing function. For example, the image sensor 100 may be mounted on electronic devices such as cameras, smartphones, wearable devices, Internet of things (IoT) devices, home appliances, tablet personal computers (PC), personal digital assistants (PDA), portable multimedia players (PMP), navigation, drones, advanced driver assistance systems (ADAS), and the like. Additionally, the image sensor 100 may be mounted on electronic devices that are included as components in vehicles, furniture, manufacturing facilities, doors, and various measuring devices.

The controller 110 may control each component 120, 130, 150, 160, and 170 included in the image sensor 100. The controller 110 may control the operation timing of each of the components 120, 130, 150, 160, and 170 using control signals. In an embodiment, the controller 110 may receive a mode signal indicating an imaging mode from an application processor, and generally control the image sensor 100 based on the received mode signal. For example, the application processor may determine the imaging mode of the image sensor 100 according to various scenarios such as the illumination of the imaging environment, the user's resolution setting, and the sensed or learned state, and may provide the determined result to the controller 110 as a mode signal. The controller 110 may control the plurality of pixels of the pixel array 140 to output pixel signals according to the imaging mode, the pixel array 140 may output a pixel signal for each of the plurality of pixels and pixel signals for some of the plurality of pixels, and the readout circuit 150 may sample and process pixel signals received from the pixel array 140. The timing generator 120 may generate a signal that serves as a reference for the operation timing of the components of the image sensor 100. The timing generator 120 may control the timing of the row driver 130, the readout circuit 150, and the ramp signal generator 160. The timing generator 120 may provide a control signal that controls the timing of the row driver 130, the readout circuit 150, and the ramp signal generator 160.

The controller may be a processor (i.e., a hardware circuit), such as a microprocessor, a CPU (Central Processing Unit), a GPU (graphics processor), a digital signal processor (DSP), a field-programmable gate array (FPGA), etc., and may be part of a computer. Such a controller may be formed by several interconnected controllers and may be configured by software.

The pixel array 140 may include a plurality of pixels PX, each pixel PX being connected to a respective row line RL of a plurality of row lines RL and a respective column line LL of a plurality of column lines LL. In an embodiment, each pixel PX may include at least one photodiode. A photodiode may detect incident light and convert the incident light into an electrical signal according to the amount of light—for example, a plurality of analog pixel signals. In examples, the photodiode may be a pinned diode, or the like. Additionally, the photodiode may be a single-photon avalanche diode (SPAD) applied to a 3D sensor pixel. The level of the analog pixel signal output from the photodiode may be proportional to the amount of charge output from the photodiode. For example, the level of the analog pixel signal output from the photodiode may be determined depending on the amount of light received into the pixel array 140.

The plurality of row lines RL extend in a first direction and may be connected to the pixels PX positioned in the first direction. For example, a control signal output from the row driver 130 to the row line RL may be transmitted to the gates of transistors of the plurality of pixels PX connected to the row line RL. The column line LL extends in a second direction intersecting the first direction and may be connected to the pixels PX positioned in the second direction. A plurality of pixel signals output from the plurality of pixels PX may be transmitted to the readout circuit 150 through a plurality of column lines LL.

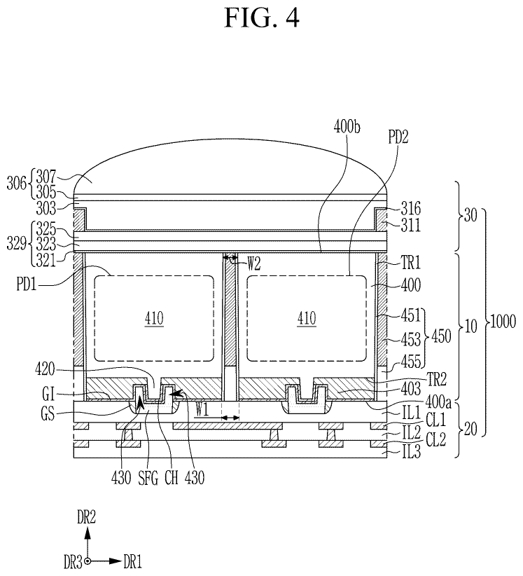

A color filter layer and a micro-lens layer may be positioned on the pixel array 140. The microlens layer includes a plurality of microlenses, each of which may be positioned on at least one corresponding pixel PX. The color filter layer includes color filters such as red, green, and blue, and may additionally include a white filter. For a single pixel PX, a color filter of one color may be positioned between the pixel PX and the corresponding microlens. The specific structures of the color filter layer and microlens layer will be described herein with respect to FIG. 4.

The row driver 130 may generate a control signal for driving the pixel array 140 in response to a control signal from the timing generator 120, and provide the control signal to the plurality of pixels PX of the pixel array 140 through the plurality of row lines RL. In an embodiment, the row driver 130 may control the pixel PX to sense incident light in row line units. A row line unit may include at least one row line RL. For example, the row driver 130 may provide a transmission signal TS, a reset signal RS, a selection signal SEL, etc. to the pixel array 140 as described herein.

The readout circuit 150 may convert a pixel signal (or electrical signal) from the pixel PX connected to the row line RL selected from among the plurality of pixels PX into a pixel value representing the quantity of light in response to a control signal from the timing generator 120. The readout circuit 150 may convert a pixel signal output through a corresponding column line LL into a pixel value. For example, the readout circuit 150 may convert a pixel signal into a pixel value by comparing the ramp signal and the pixel signal. The pixel value may be image data having a plurality of bits. Specifically, the readout circuit 150 may include a selector, a plurality of comparators, and a plurality of counter circuits.

The ramp signal generator 160 may generate a reference signal and transmit the reference signal to the readout circuit 150.

The ramp signal generator 160 may include a current source, a resistor, and a capacitor. The ramp signal generator 160 may generate a plurality of ramp signals that fall or rise with a slope determined according to the current size of the variable current source or the resistance value of the variable resistor, by adjusting the ramp voltage applied to the ramp resistance by controlling the current size of the variable current source or the resistance value of the variable resistor.

The data buffer 170 may store pixel values of the plurality of pixels PX connected to the selected column line LL transmitted from the readout circuit 150, and output the stored pixel values in response to an enable signal from the controller 110.

The image signal processor 180 may perform image signal processing on the image signal received from the data buffer 170. For example, the image signal processor 180 may receive a plurality of image signals from the data buffer 170, and generate one image by synthesizing the received image signals.

In an embodiment, a plurality of pixels may be grouped in the form of M*N (where M and N are integers greater than or equal to 2) to form a single unit pixel group. The M*N form may be a form in which M pixels are arranged in the arrangement direction of the column line LL and N pixels are arranged in the arrangement direction of the row line RL. For example, a single unit pixel group may include a plurality of pixels arranged in a 2*2 form, and a single unit pixel group may output a single analog pixel signal. Embodiments are not limited to a single pixel, but may also be applied to a unit pixel group.

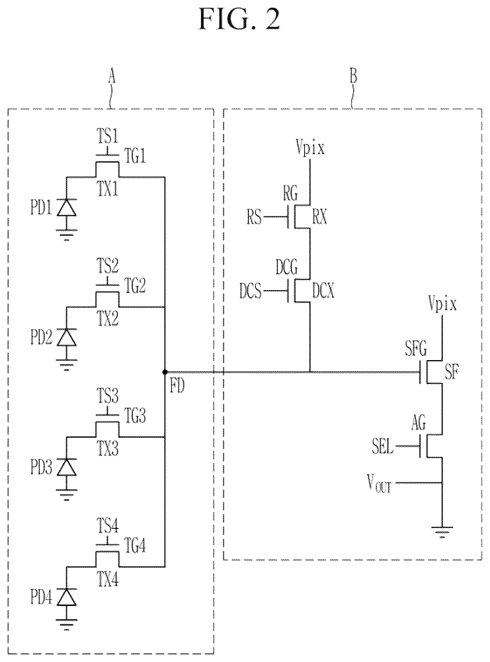

FIG. 2 is a circuit diagram of one pixel included in an image sensor according to embodiments of the present disclosure.

Referring to FIG. 2, a single pixel may include a plurality of photodiodes PD1, PD2, PD3, and PD4. Each photodiode PD of the plurality of photodiodes PD1, PD2, PD3, and PD4 may perform photoelectric conversion. As shown in FIG. 2, each photodiode PD of the plurality of photodiodes PD1, PD2, PD3, and PD4 may be connected to a single floating diffusion FD. Although FIG. 2 illustrates a configuration in which four photodiodes are connected to a single floating diffusion FD, this is only an example, and the number of photodiodes PD connected to a single floating diffusion FD may vary depending on the embodiment.

The following description focuses on the first photodiode PD1, but applies equally to other photodiodes such as PD2, PD3, and PD4.

The first photodiode PD1 may generate and accumulate charges according to the amount of light received. The first photodiode PD1 may include an anode connected to ground and a cathode connected to one end of a first transmission transistor TX1. A first transmission signal TS1 is supplied to a gate TG1 of the first transmission transistor TX1, and one end of the first transmission transistor TX1 may be connected to the floating diffusion FD. When the first transmission transistor TX1 is turned on by the first transmission signal TS1, the charge stored in the first photodiode PD1 may be transmitted to the floating diffusion FD. The floating diffusion FD may retain charges transmitted from a photodiode PD.

Each transmission transistor TX of a plurality of transmission transistors TX1, TX2, TX3, and TX4 may include a corresponding gate electrode TG of a plurality of gate electrodes TG1, TG2, TG3, and TG4 connected between a photodiode PD of the plurality of photodiodes PD1, PD2, PD3, and PD4 and the floating diffusion FD and receiving a corresponding transmission signal of a plurality of transmission signals TS1, TS2, TS3, and TS4. For example, the first transmission transistor TX1 may be connected between the first photodiode PD1 and the floating diffusion FD and may include the gate electrode TG1 that receives the first transmission signal TS1. The number of the plurality of transmission transistors TX1, TX2, TX3, and TX4 may be equal to the number of photodiodes PD of the plurality of photodiodes PD1, PD2, PD3, and PD4.

A reset transistor RX is connected between a power supply Vpix and the floating diffusion FD and may include a gate electrode RG that receives the reset signal RS.

The reset transistor RX may periodically reset the charges accumulated in the floating diffusion FD. The drain electrode of the reset transistor RX is connected to the source electrode of a dual-conversion transistor DCX, and the source electrode may be connected to the power supply Vpix. When the reset transistor RX is turned on, the power supply Vpix connected to the source electrode of the reset transistor RX may apply power supply voltage Vpix to the floating diffusion FD. Therefore, when the reset transistor RX is turned on, the charges accumulated in the floating diffusion FD are discharged, so that the floating diffusion FD may be reset.

The dual-conversion transistor DCX is positioned between the reset transistor RX and the floating diffusion FD and may include a gate electrode DCG that receives a dual conversion signal DCS. The dual-conversion transistor DCX may reset the floating diffusion FD together with the reset transistor RX.

The drain electrode of the dual-conversion transistor DCX is connected to the floating diffusion FD, and the source electrode of the dual-conversion transistor DCX may be connected to the drain electrode of the reset transistor RX. When the reset transistor RX and the dual-conversion transistor DCX are turned on, the power supply Vpix connected to the source electrode of the reset transistor RX may apply power supply voltage Vpix to the floating diffusion FD through the dual-conversion transistor DCX. Therefore, the charges accumulated in the floating diffusion FD may be discharged, and the floating diffusion FD may be reset.

An amplifying transistor SF may output a pixel signal according to the voltage of the floating diffusion FD. A gate SFG of the amplifying transistor SF is connected to the floating diffusion FD, the power supply voltage Vpix is supplied to the source electrode of the amplifying transistor SF, and the drain electrode of the amplifying transistor SF may be connected to one end of a selection transistor SEL. The amplifying transistor SF forms a source follower circuit and may output a voltage of a level corresponding to the charge accumulated in the floating diffusion FD as a pixel signal. As will be described separately herein, in the image sensor according to the present embodiment, the channel material of the amplifying transistor SF may be different from the channel material of other transistors. Specifically, the channel material of the amplifying transistor SF may include or be a two-dimensional material. The specific structure will be described separately herein.

When the selection transistor SEL is turned on by the selection signal SEL, a pixel signal from the amplifying transistor SF may be transmitted to the readout circuit. The selection signal SEL is applied to a gate electrode AG of the selection transistor SEL, and the drain electrode of the selection transistor SEL may be connected to an output wiring Vout that outputs a plurality of pixel signals.

The operation of the image sensor is described as follows with reference to FIG. 2. First, in a state where light is blocked, the power supply voltage Vpix is applied to the drain electrode of the reset transistor RX and the drain electrode of the amplifying transistor SF, and the reset transistor RX and the dual-conversion transistor DCX are turned on to release charges remaining in the floating diffusion FD. After that, when the reset transistor RX is turned off and external light is incident on the photodiodes PD1, PD2, PD3, and PD4, electron-hole pairs are generated in each of the photodiodes PD1, PD2, PD3, and PD4. Holes move to the p-type impurity region of the photodiodes PD1, PD2, PD3, and PD4, and electrons move to the n-type impurity region and accumulate. When the transmission transistors TX1, TX2, TX3, and TX4 are turned on, charges such as electrons and holes are transmitted to the floating diffusion FD and accumulated. The gate bias of the amplifying transistor SF changes in proportion to the amount of accumulated charge, which causes a change in the source potential of the amplifying transistor SF. In embodiments, when the selection transistor SEL is turned on, a charge-driven signal is read through the output wiring Vout.

The wiring may be electrically connected to at least one of the gate electrodes TG1, TG2, TG3, and TG4 of the transmission transistors TX1, TX2, TX3, and TX4, the gate electrode SFG of the amplifying transistor SF, the gate electrode DCG of the dual-conversion transistor DCX, the gate electrode RG of the reset transistor RX, and the gate electrode AG of the selection transistor SEL. The wiring may include a power voltage transmission wiring that applies the power voltage Vpix to the source electrode of the reset transistor RX or to the source electrode of the amplifying transistor SF. The wiring may include the output wiring Vout connected to the selection transistor SEL.

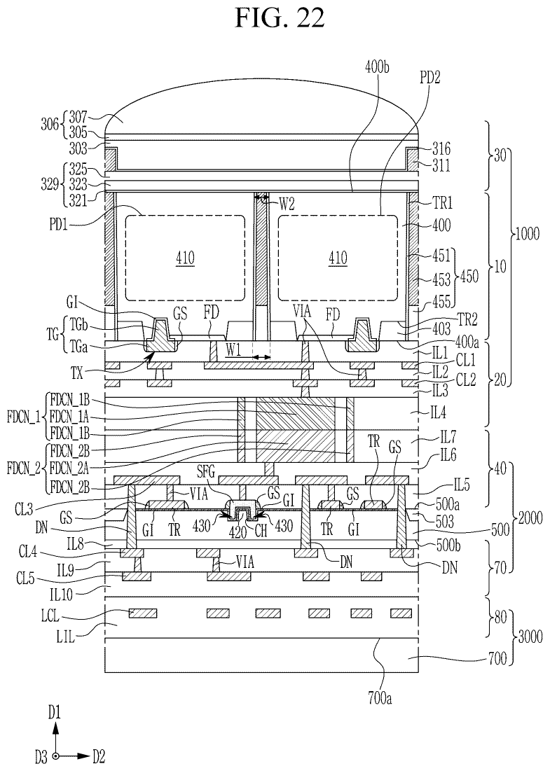

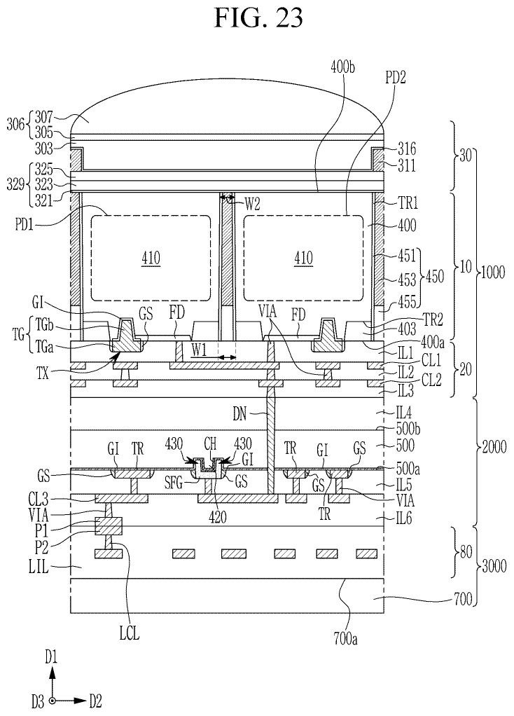

As will be described in detail separately in FIGS. 22 and 23 herein, some transistors in the image sensor according to the present embodiment may be located on different substrates. For example, in an embodiment, the image sensor may include a first chip 1000, a second chip 2000, and a third chip 3000. In embodiments, the transistor included in the portion indicated as A in the circuit diagram of FIG. 2 may be positioned in the first chip 1000, and the transistor included in the portion indicated as B may be positioned in the second chip 2000. The floating diffusion FD of the first chip 1000 may be connected to the second chip 2000 through floating diffusion connection nodes FDCN_1 and FDCN_2 (see FIG. 22), the specific connection structure of which is described herein. However, this is an example and all of the transistors shown in the circuit diagram of FIG. 2 may be positioned in the first chip 1000. In this specification, an embodiment in which all of the transistors illustrated in the circuit diagram of FIG. 2 are positioned in the first chip 1000 is first described, and then an embodiment in which some of the transistors are positioned in the second chip 2000 is described.

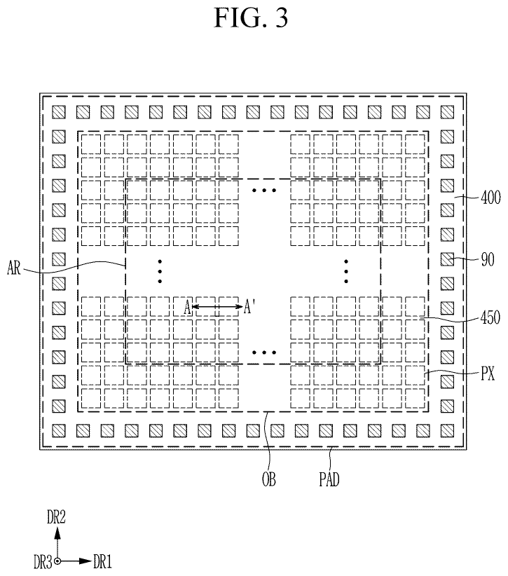

FIG. 3 is a top plan view showing an image sensor according to embodiments of the present disclosure. FIG. 4 illustrates a part of a cross-section of a single pixel PX of an image sensor according to the present embodiment. However, the descriptions of FIGS. 3 and 4 are only examples and the present disclosure is not limited thereto.

Referring to FIGS. 3 and 4 simultaneously, the image sensor according to the present embodiment may include the first chip 1000. The first chip 1000 may include a photoelectric conversion layer 10, a first wiring region 20, and a light transmitting layer 30. The photoelectric conversion layer 10 may include a first substrate 400, an isolation pattern 450, a device isolation pattern 403, and a photoelectric conversion region 410 positioned in the first substrate 400. Light incident from the outside may be converted into an electrical signal in the photoelectric conversion region 410.

Referring to FIG. 3, the first substrate 400 may include a pixel array region AR, an optical black region OB, and a pad region PAD on a plane. The pixel array region AR may be positioned in the central region of the first substrate 400 on a plane. The pixel array region AR may include a plurality of pixels PX. The pixels PX may output a photoelectric signal from incident light. The pixels PX may be positioned in rows parallel to a first direction DR1 and in columns parallel to the second direction DR2. The pixel PX may include a plurality of photoelectric conversion regions.

The pad region PAD is positioned at an edge portion of the first substrate 400 and may surround the pixel array region AR. A plurality of pad terminals 90 may be positioned in the pad region PAD. The pad terminals 90 may output electrical signals generated by the pixel PX to the outside. Alternatively, an external electrical signal or voltage may be transmitted to the pixel PX through the pad terminal 90. Because the pad region PAD is positioned at the edge portion of the first substrate 400, the pad terminal 90 may be easily connected to the outside.

The optical black region OB may be positioned between the pixel array region AR and the pad region PAD of the first substrate 400. The optical black region OB may surround the pixel array region AR. A pixel positioned in the optical black region OB may include a dummy region instead of the photoelectric conversion region 410. The signal generated in the dummy region may be used as information to remove process noise.

Hereinafter, the stacked structure of the image sensor is described in detail with reference to FIG. 4. The first chip 1000 includes the photoelectric conversion layer 10 and may be a layer that generates a photoelectric signal. Although not specifically illustrated in FIG. 4, all of the transistors illustrated in FIG. 2 may be positioned in the first chip 1000. However, this is an example, and in another embodiment, some of the transistors shown in FIG. 2 may be positioned in the first chip 1000, and some may be positioned in the second chip 2000 (see FIGS. 22 and 23).

The first chip 1000 includes the first substrate 400. The first substrate 400 may include a first surface 400a and a second surface 400b facing each other. Light may be incident on the second surface 400b of the first substrate 400. The first wiring region 20 may be positioned on the first surface 400a of the first substrate 400, and the light transmitting layer 30 may be positioned on the second surface 400b of the first substrate 400. The first substrate 400 may be a semiconductor substrate or a silicon on insulator (SOI) substrate. For example, the semiconductor substrate may include a silicon substrate, a germanium substrate, or a silicon-germanium substrate. The first substrate 400 may include a first conductivity-type impurity. For example, the first conductivity-type impurity may be p-type impurity such as aluminum (Al), boron (B), indium (In), and gallium (Ga).

The first substrate 400 may include the isolation pattern 450. The isolation pattern 450 may partition a plurality of unit pixels and a plurality of photoelectric conversion regions within a single pixel.

FIG. 4 illustrates a part of a cross-section of a single pixel, showing two photoelectric conversion regions in the cross-section. However, this is a virtual cross-section for convenience of description, and the present disclosure is not limited thereto. For example, as shown in FIG. 2, a single pixel may include four photoelectric conversion regions, and the number of photoelectric conversion regions included in a single pixel may vary.

The first substrate 400 may include the photoelectric conversion region 410. The photoelectric conversion region 410 may perform the same function and role as the photodiodes PD1, PD2, PD3, and PD4 illustrated in FIG. 2. FIG. 4 illustrates the first photodiode PD1 and the second photodiode PD2.

The photoelectric conversion region 410 may be a region doped with a second conductivity-type impurity in the first substrate 400. The second conductivity-type impurity may have a conductivity type opposite to that of the first conductivity-type impurity. The second conductivity-type impurity may be n-type impurity such as phosphorus, arsenic, bismuth, and antimony. For example, each photoelectric conversion region 410 may include a first region adjacent to the first surface 400a and the second region adjacent to the second surface 400b. There may be a difference in impurity concentration between the first region and the second region of the photoelectric conversion region 410. Therefore, the photoelectric conversion region 410 may have a potential gradient between the first surface 400a and the second surface 400b of the first substrate 400. However, as another example, the photoelectric conversion region 410 may not have a potential gradient between the first surface 400a and the second surface 400b of the first substrate 400.

The first substrate 400 and the photoelectric conversion region 410 may form a photodiode. For example, a photodiode may be formed by a p-n junction between the first substrate 400 of the first conductivity type and the photoelectric conversion region 410 of the second conductivity type. The photoelectric conversion region 410 configuring the photodiode may generate and accumulate photoelectric charges in proportion to the intensity of incident light.

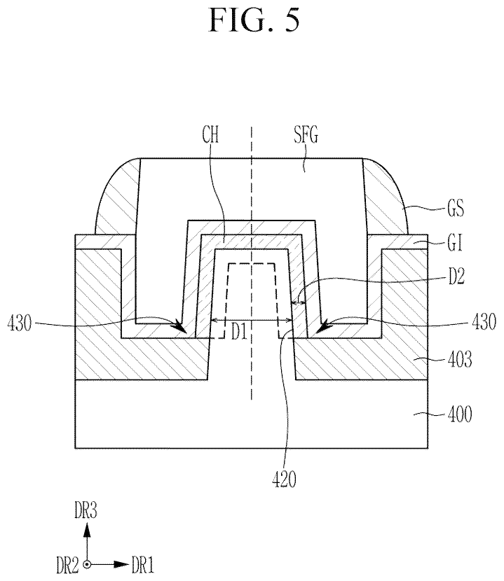

Referring to FIG. 4, the isolation pattern 450 may be positioned on the first substrate 400. The isolation pattern 450 on a plane may have a lattice structure. As will be described herein with respect to FIG. 5, the isolation pattern 450 may be positioned between the plurality of photodiodes PD1, PD2, PD3, and PD4 included in a single pixel while partitioning each pixel on a plane.

Referring to FIG. 4, the isolation pattern 450 may be positioned in a first trench TR1. The first trench TR1 may be recessed from the first surface 400a of the first substrate 400. The isolation pattern 450 may extend from the first surface 400a of the first substrate 400 toward the second surface 400b. The isolation pattern 450 may be a deep trench isolation (DTI) film. The isolation pattern 450 may penetrate the first substrate 400. The vertical height of the isolation pattern 450 may be substantially equal to the vertical thickness of the first substrate 400. For example, the width of the isolation pattern 450 may gradually decrease from the first surface 400a of the first substrate 400 to the second surface 400b. The width on the first surface 400a of the isolation pattern 450 may be a first width W1, and the width on the second surface 400b of the isolation pattern 450 may be a second width W2. For example, the first width W1 may be greater than the second width W2.

The isolation pattern 450 may include a first isolation pattern 451, a second isolation pattern 453, and a capping pattern 455. The first isolation pattern 451 may be positioned along the sidewall of the first trench TR1. The first isolation pattern 451 may include, for example, a silicon-based insulating material (e.g., silicon nitride, silicon oxide, or silicon oxynitride) or a high-k material (e.g., hafnium oxide or aluminum oxide). As another example, the first isolation pattern 451 may include a plurality of layers, each of which may include different materials. The first isolation pattern 451 may have a lower refractive index than the first substrate 400. Accordingly, crosstalk phenomena between photoelectric conversion regions positioned on the first substrate 400 may be prevented or reduced.

The second isolation pattern 453 may be positioned in the first isolation pattern 451. For example, the sidewall of the second isolation pattern 453 may be surrounded by the first isolation pattern 451. The first isolation pattern 451 may be positioned between the second isolation pattern 453 and the first substrate 400. The second isolation pattern 453 may be separated from the first substrate 400 by the first isolation pattern 451. Accordingly, when the image sensor operates, the second isolation pattern 453 may be electrically separated from the first substrate 400. The second isolation pattern 453 may include a crystalline semiconductor material—for example, polycrystalline silicon. For example, the second isolation pattern 453 may further include a dopant, and the dopant may be a first conductivity-type impurity or a second conductivity-type impurity.

For example, the second isolation pattern 453 may be doped polycrystalline silicon. Alternatively, the second isolation pattern 453 may be an undoped crystalline semiconductor material. For example, the second isolation pattern 453 may be undoped polycrystalline silicon. The term “undoped” may refer to a situation where no intentional doping process is performed.

The dopant may include an n-type dopant and a p-type dopant.

The capping pattern 455 may be positioned on the lower surface of the second isolation pattern 453. The capping pattern 455 may be positioned adjacent to the first surface 400a of the first substrate 400. The capping pattern 455 may include a non-conductive material. For example, the capping pattern 455 may include a silicon-based insulating material (e.g., silicon nitride, silicon oxide, or silicon oxynitride) or a high-k material (e.g., hafnium oxide or aluminum oxide). Accordingly, the isolation pattern 450 may prevent photoelectric charges generated by light incident on the photoelectric conversion region from being incident on another adjacent photoelectric conversion region due to random drift. For example, the isolation pattern 450 may prevent crosstalk phenomena between photoelectric conversion regions.

The device isolation pattern 403 may be positioned in the first substrate 400. For example, the device isolation pattern 403 may be positioned in the second trench TR2. The second trench TR2 may be recessed from the first surface 400a of the first substrate 400. The device isolation pattern 403 may be a shallow trench isolation (STI) film. The upper surface of the device isolation pattern 403 may be positioned in the first substrate 400. The width of the device isolation pattern 403 may gradually decrease from the first surface 400a of the first substrate 400 to the second surface 400b. The upper surface of the device isolation pattern 403 may be vertically spaced apart from the photoelectric conversion region 410. The isolation pattern 450 may overlap a portion of the device isolation pattern 403. The device isolation pattern 403 may include the same material as the first isolation pattern 451 of the isolation pattern 450, in which case the boundary between the device isolation pattern 403 and the first isolation pattern 451 may not be recognized. However, this is only an example, and the present disclosure is not limited thereto.

In FIG. 4, a configuration is illustrated in which the device isolation pattern 403, the isolation pattern 450, and the first surface 400a of the first substrate 400 are positioned on the same plane, but this is only an example, and the present embodiment is not limited thereto. For example, the device isolation pattern 403, the isolation pattern 450, and the first surface 400a of the first substrate 400 may not be coplanar. The device isolation pattern 403 and the isolation pattern 450 may be positioned to protrude or recede from the first surface 400a of the first substrate 400.

In addition, in FIG. 4, the upper surface of the device isolation pattern 403 and the upper surface of the isolation pattern 450 are illustrated as being flat, but this is only an example, and the upper surface of the device isolation pattern 403 and the upper surface of the isolation pattern 450 may include curved surfaces.

Referring to FIG. 4, the amplifying transistor SF described herein with respect to FIG. 2 may be positioned on the first surface 400a of the first substrate 400. Although not shown in FIG. 4, other transistors shown in FIG. 2 may also be positioned on the first surface 400a of the first substrate 400. This embodiment is characterized by the structure of the amplifying transistor SF, and the following description focuses on the structure of the amplifying transistor SF.

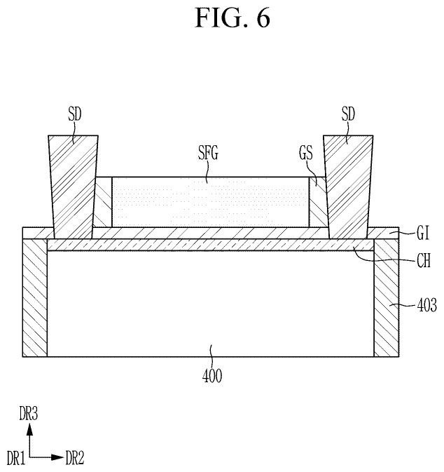

FIG. 5 is an enlarged view of the amplifying transistor SF of FIG. 4. FIG. 6 illustrates a cross-section in the dotted line direction—i.e., a cross-section in the second direction DR2—of the amplifying transistor SF of FIG. 5. The structure of the amplifying transistor SF is described herein with reference to FIGS. 4 to 6.

Referring to FIGS. 4 to 6, the amplifying transistor SF may include recessed portions 430 formed in the device isolation pattern 403 of the first substrate 400, a pin 420 positioned between the recessed portions 430, a channel layer CH positioned along the upper surface and side surface of the pin 420, the gate electrode SFG filling the recessed portions 430, a gate insulating film GI positioned between the gate electrode SFG and the channel layer CH, and a gate spacer GS positioned on both sides of the gate electrode SFG.

Referring to FIGS. 4 and 5, the amplifying transistor SF includes the recessed portions 430 formed by etching the first substrate 400. More specifically, the recessed portions 430 may be formed in the device isolation pattern 403 of the first substrate 400. In the cross-section of FIG. 5, the recessed portions 430 may be positioned on both sides in the first direction DR1, and the pin 420 may be positioned between two recessed portions 430. The pin 420 is a region of the first substrate 400 positioned between two recessed portions 430 where the first substrate 400 protrudes more than the recessed portions 430. Referring to FIG. 4, the channel layer CH may be positioned on the upper surface and side surface of the pin 420. For example, the channel layer CH may be positioned between two recessed portions 430, and specifically, may be positioned along the upper surface and side surface of the pin 420.

Referring to FIG. 5, a width D1 of the pin 420 in the first direction DR1 may be 10 nm to 50 nm, or 15 nm to 45 nm, or 20 nm to 40 nm. Additionally, a thickness D2 of the channel layer CH may be 1 nm to 10 nm, or 2 nm to 9 nm, or 3 nm to 8 nm. This is the numerical range for the amplifying transistor SF to operate efficiently.

The channel layer CH may include or be a two-dimensional material. The two-dimensional material may be for example, a metal dichalcogenide, represented by MX₂. M is a transition metal, which may include molybdenum or tungsten, for example, and X is a chalcogen atom, which may include sulfur, selenium, or tellurium. Specifically, the two-dimensional material may include, but is not limited to, at least one of molybdenum disulfide (MoS₂), molybdenum diselenide (MoSe₂), tungsten disulfide (WS₂), tungsten diselenide (WSe₂), or black phosphorus (BP).

In example embodiments of an image sensor according the channel layer CH of the amplifying transistor SF includes a two-dimensional material. The transistor applied with the two-dimensional material may improve the device characteristics of the amplifying transistor SF by acting as a driving current booster due to enhanced mobility. In addition, because the two-dimensional material is a material that does not form dangling bonds at the interface with the gate insulating film GI, the interface characteristics and pixel noise of the amplifying transistor SF are improved. Additionally, the dielectric constant of the two-dimensional material is greater than that of silicon oxide, and may have high effective current and transconductance (Gm) performance.

Referring to FIG. 2, the amplifying transistor SF is connected to the floating diffusion FD of the photodiode PD. In examples, when the amplifying transistor SF includes a silicon channel layer, dangling bonds may be formed at the interface between the silicon channel layer and the gate insulating film during operation of the amplifying transistor SF. The dangling bonds may cause uneven charge traps in the amplifying transistor SF. The dangling bonds and uneven charge traps of the amplifying transistor SF are the main causes of noise in the image sensor.

In examples, the amplifying transistor SF of the image sensor according to the present embodiment uses a two-dimensional material as the channel layer CH. The channel layer CH containing a two-dimensional material does not form dangling bonds at the interface with the gate insulating film GI. Therefore, uneven charge trapping may be reduced, the amplifying transistor may operate stably, and the image sensor generate less noise.

For example, the main cause of noise in the image sensor is the uneven charge trapping of the amplifying transistor SF, and the image sensor according to the present embodiment is characterized by forming the channel layer of the amplifying transistor SF with a two-dimensional material. In example embodiments, the channels of other transistors included in the image sensor do not contain two-dimensional material, and therefore the amplifying transistor SF and other transistors may contain different channel materials.

A channel region of the amplifying transistor SF according to the present embodiment shown in FIG. 5 is drawn with a dotted line. As shown in FIG. 5, a portion of the pin 420 positioned between the channel layers CH may operate as a channel region. In the doping process of the channel layer CH, the pin 420 in contact with the channel layer CH is doped, and the doped pin 420 region may become a channel region. The dopant may be an n-type dopant. For example, n-type impurities such as phosphorus, arsenic, bismuth, and antimony may be doped.

Referring to FIG. 5, the gate electrode SFG may be positioned on the recessed portions 430 and the pin 420. The gate electrode SFG may be positioned to overlap the recessed portions 430 and the pin 420 in a third direction DR3 while filling the space within the recessed portions 430.

As shown in FIG. 5, the lowermost part of the gate electrode SFG may not overlap the channel layer CH in the third direction DR3. For example, the channel layer CH may not be positioned at the lowest surface of the gate electrode SFG. Therefore, the lower part of the recessed portions 430 may be excluded from the channel region. By limiting the channel layer CH region in this way, the occurrence of threshold voltage modulation (Vth modulation) may be prevented.

Referring to FIGS. 5 and 6, the gate insulating film GI may be positioned on the lower surface of the gate electrode SFG. The gate insulating film GI may be positioned on the first surface 400a of the first substrate 400. The gate spacer GS may be positioned on the sidewall of the gate electrode SFG. The gate spacer GS may include silicon nitride, silicon carbonitride or silicon oxynitride.

Referring to FIG. 6, a source/drain electrode SD may be positioned in contact with the channel layer CH. As shown in FIG. 6, the source/drain electrode SD and the gate electrode SFG may be insulated by the gate spacer GS. The source/drain electrode SD may include, but is not limited to, tungsten.

Although not shown in FIGS. 4 to 6, the transmission transistor TX, the reset transistor RX, the dual-conversion transistor DCX, and the selection transistor SEL may be positioned on the first surface 400a of the first substrate 400. The channel of such transistors may not contain two-dimensional materials. The channels of the transmission transistor TX, the reset transistor RX, the dual-conversion transistor DCX, and the selection transistor SEL may have a channel material of doped silicon. For example, in the image sensor according to the present embodiment, the channel material of the amplifying transistor SF and the channel material of the remaining transistors may be different. By forming the channel layer of the amplifying transistor SF with a two-dimensional material, the noise generated by the image sensor may be reduced.

In addition, although the present embodiment illustrates a configuration in which the amplifying transistor SF is positioned on the first substrate 400, in another embodiment, the amplifying transistor SF may be positioned on another substrate positioned opposite the first substrate 400. These embodiments will be described separately herein with reference to FIGS. 22 and 23.

Referring to FIG. 4, the first wiring region 20 is positioned on the first surface 400a of the first substrate 400 and may include a plurality of insulating layers IL1, IL2, and IL3, a plurality of wiring layers CL1 and CL2, and a via VIA.

The insulating layer may include a first insulating layer IL1, a second insulating layer IL2, and a third insulating layer IL3.

The first insulating layer IL1 may cover the first surface 400a of the first substrate 400. The first insulating layer IL1 may cover the gate electrode SFG of the amplifying transistor SF. The second insulating layer IL2 may be positioned on the first insulating layer IL1. The third insulating layer IL3 may be positioned on the second insulating layer IL2.

The first to third insulating layers IL1, IL2, and IL3 may each be a non-conductive material. For example, the first to third insulating layers IL1, IL2, and IL3 may each be a silicon-based insulating material such as silicon oxide, silicon nitride, or silicon oxynitride.

The first wiring region 20 may include the first wiring layer CL1 and the second wiring layer CL2. The first wiring layer CL1 may be positioned within the second insulating layer IL2. The second wiring layer CL2 may be positioned within the third insulating layer IL3.

A plurality of vias VIA may be positioned within the first insulating layer IL1, the second insulating layer IL2, and the third insulating layer IL3. The via VIA may connect a floating diffusion (not shown), the first wiring layer CL1, and the second wiring layer CL2 to each other.

The first wiring layer CL1, the second wiring layer CL2, and the via VIA may include or be a metal material. For example, the first wiring layer CL1, the second wiring layer CL2, and the via VIA may include or be copper (Cu).

The first chip 1000 may include the light transmitting layer 30. The light transmitting layer 30 may include an insulating structure 329, a color filter 303, and a microlens portion 306. The light transmitting layer 30 may collect and filter light incident from the outside and provide the light to the photoelectric conversion region 410.

The color filter 303 may be positioned on the second surface 400b of the first substrate 400. The color filters 303 may each be positioned in a single pixel PX. In each pixel PX, the color filter 303 may include primary color filters. The color filter 303 may include a first color filter, a second color filter, and a third color filter having different colors. For example, the first color filter, the second color filter, and the third color filter may include green, red, and blue color filters, respectively. The first color filter, the second color filter, and the third color filter may be arranged in a Bayer pattern. As another example, the first color filter, the second color filter, and the third color filter may include colors such as cyan, magenta, or yellow.

The insulating structure 329 may be positioned between the second surface 400b of the first substrate 400 and the color filter 303. The insulating structure 329 may prevent reflection of light so that light incident on the second surface 400b of the first substrate 400 may smoothly reach the photoelectric conversion region 410. The insulating structure 329 may be referred to as an anti-reflection structure.

The insulating structure 329 may include a first fixed charge film 321, a second fixed charge film 323, and a planarized film 325 sequentially stacked on the second surface 400b of the first substrate 400. Each of the first fixed charge film 321, the second fixed charge film 323, and the planarized film 325 may include a different material. The first fixed charge film 321 may include any one of aluminum oxide, tantalum oxide, titanium oxide, and hafnium oxide. The second fixed charge film 323 may include any one of aluminum oxide, tantalum oxide, titanium oxide, and hafnium oxide. For example, the first fixed charge film 321 may be aluminum oxide, the second fixed charge film 323 may be hafnium oxide, and the planarized film 325 may be silicon oxide. In another embodiment, a silicon anti-reflection film (not shown) may be interposed between the second fixed charge film 323 and the planarized film 325. The anti-reflection film may be silicon nitride.

A microlens portion 306 may be positioned on the color filter 303. The microlens portion 306 may include a planarized portion 305 in contact with the color filter 303 and a microlens 307 positioned on the planarized portion 305. The planarized portion 305 may contain, for example, organic material. As another example, the planarized portion 305 may include silicon oxide or silicon oxynitride. The microlens 307 may have a convex shape so as to focus incident light. Each microlens 307 may vertically overlap the photoelectric conversion region 410. The shape of the lens may vary. For convenience of description, FIG. 4 illustrates a shape in which a single microlens 307 overlaps two photoelectric conversion regions 410 in cross-section. However, on a plane, a single microlens 307 may be positioned in a shape that overlaps four photoelectric conversion regions 410. However, this is only an example, and the number of microlenses 307 positioned in a single pixel PX may vary.

The light transmitting layer 30 may further include a Bayer pattern 311 and a protective film 316. The Bayer pattern 311 may be positioned between adjacent color filters 303 to separate them from each other. The Bayer pattern 311 may be positioned on the insulating structure 329. For example, the Bayer pattern 311 may have a lattice structure. The Bayer pattern 311 may include a material having a lower refractive index than the color filter 303. The Bayer pattern 311 may include an organic material. For example, the Bayer pattern 311 may be a polymer layer containing silica nanoparticles. The Bayer pattern 311 has a low refractive index, which may increase the amount of light incident on the photoelectric conversion region 410 and reduce crosstalk between pixels PX. For example, the light receiving efficiency may be increased in each photoelectric conversion region 410, and signal noise ratio (SNR) characteristics may be improved.

The protective film 316 may cover the surface of the Bayer pattern 311 with a substantially uniform thickness. The protective film 316 may include, for example, a single film or multiple films of at least one of an aluminum oxide film and a silicon carbide oxide film. The protective film 316 may protect the color filter 303 and have a moisture absorption function.

Hereinafter, a method for manufacturing the amplifying transistor SF according to the present embodiment will be described with reference to the drawings.

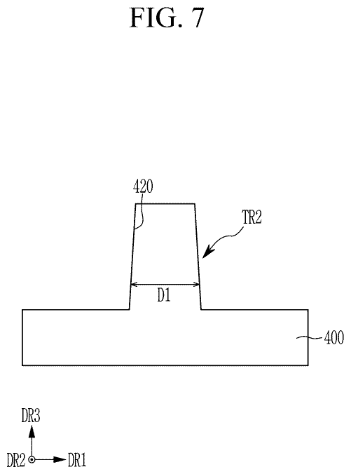

FIGS. 7 to 15 illustrate a method for manufacturing the amplifying transistor SF according to the present embodiment. FIGS. 7 to 15 illustrate a method for manufacturing the same region as in FIG. 5.

Referring to FIG. 7, the first substrate 400 is etched to form the second trench TR2. The second trench TR2 may be formed on both sides with the pin 420 in between. For example, the unetched portion of the first substrate 400 between the two second trenches TR2 may be the pin 420. In example embodiments, the width D1 of the pin 420 in the first direction DR1 may be 10 nm to 50 nm, or 15 nm to 45 nm or 20 nm to 40 nm.

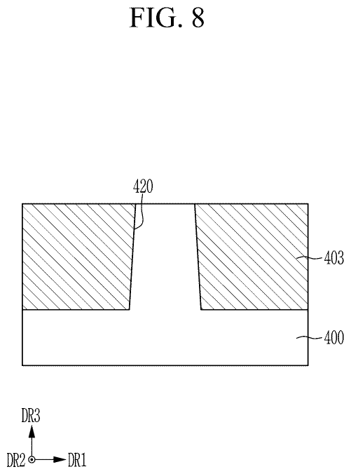

Next, referring to FIG. 8, the second trench TR2 is filled with the device isolation pattern 403. The device isolation pattern 403 may include an insulating material.

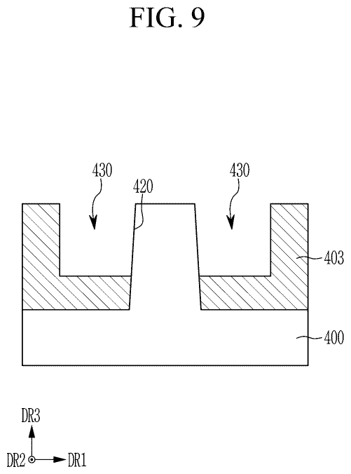

Next, referring to FIG. 9, the device isolation pattern 403 is etched to form the recessed portions 430. In example embodiments, the recessed portions 430 may be formed on both sides with the pin 420 in between. The device isolation pattern 403 may not be positioned between the pin 420 and the recessed portions 430.

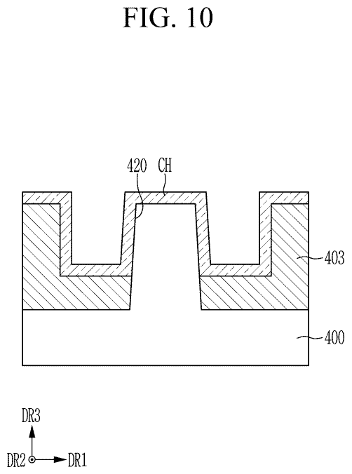

Next, referring to FIG. 10, the channel layer CH is formed on the upper surface and side surface of the recessed portions 430 and the upper surface and side surface of the pin 420. The channel layer CH may be formed by a process such as chemical vapor deposition (CVD) or plasma-enhanced chemical vapor deposition (PE-CVD). The channel layer CH may include or be a two-dimensional material as described above. The two-dimensional material may be a metal dichalcogenide, represented by MX₂. M is a transition metal, which may include molybdenum or tungsten, for example, and X is a chalcogen atom, which may include for example, sulfur, selenium, or tellurium. Specifically, the two-dimensional material may include, but is not limited to, at least one of molybdenum disulfide (MoS₂), molybdenum diselenide (MoSe₂), tungsten disulfide (WS₂), tungsten diselenide (WSe₂), or black phosphorus (BP). In example embodiments, the thickness at which the channel layer CH is formed may be 1 nm to 10 nm, or 2 nm to 9 nm, or 3 nm to 8 nm.

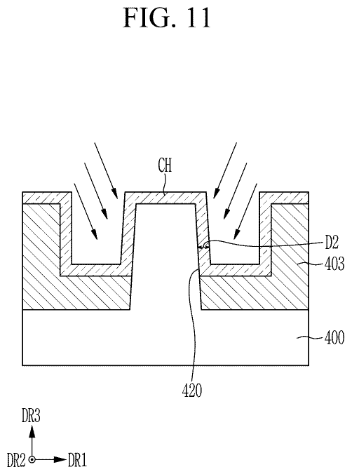

Referring to FIG. 11 below, the channel layer CH is doped. In example embodiments, the dopant may be an n-type dopant. For example, n-type impurities such as phosphorus, arsenic, bismuth, and antimony may be doped.

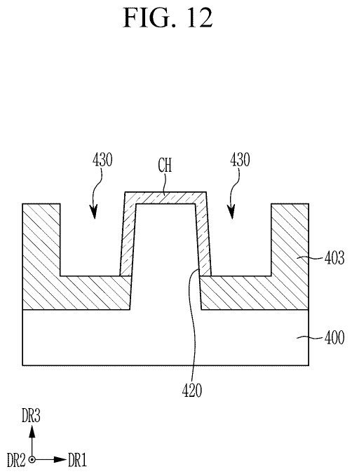

Next, referring to FIG. 12, the channel layer CH is removed from a region excluding the upper surface and side surface of the pin 420. For example, the channel layer CH is not positioned at the lower part of the recessed portions 430. By removing the channel layer CH in this region, the channel layer CH region may be limited and Vth modulation may be prevented.

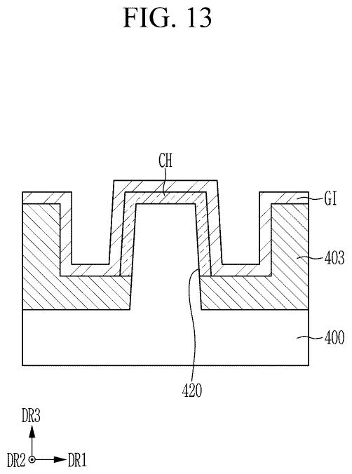

Next, referring to FIG. 13, the gate insulating film GI is formed. The gate insulating film GI may be formed on the entire surface of the channel layer CH and the recessed portions 430.

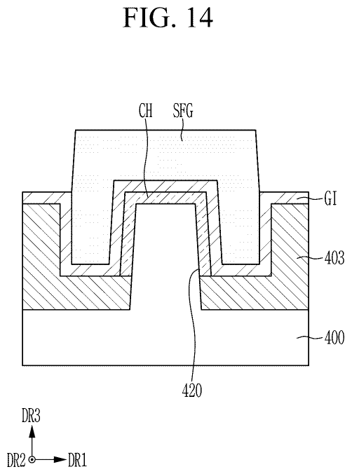

Next, referring to FIG. 14, the gate electrode SFG is formed. The gate electrode SFG may be positioned to overlap the recessed portions 430 and the pin 420 in the third direction DR3 while filling the recessed portions 430.

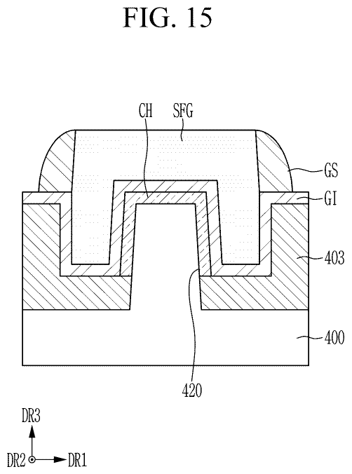

Next, referring to FIG. 15, the gate spacer GS is formed on both sides of the gate electrode SFG.

However, the manufacturing methods illustrated in FIGS. 7 to 15 are only examples, and the present disclosure is not limited thereto. The image sensor and the amplifying transistor SF according to the present embodiment may be formed in various ways.

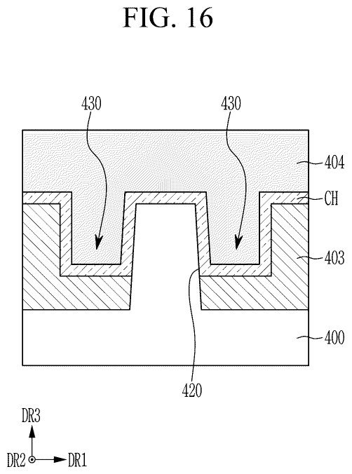

In a manufacturing method according to an embodiment, a process of forming a capping layer 404 may be further included before doping the channel layer CH. FIGS. 16 to 19 illustrate a channel doping process according to another embodiment. For example, in the manufacturing methods of FIGS. 7 to 15 described above, the doping process of the channel layer CH in FIG. 11 may be performed by a method as shown in FIGS. 16 to 19 below.

In the manufacturing method according to the present embodiment, the manufacturing methods up to FIG. 10 are the same. For example, after the channel layer CH is formed as in FIG. 10, the capping layer 404 may be formed as shown in FIG. 16. The capping layer 404 may be positioned to fill the recessed portions 430 and may also be formed on the first substrate 400. The capping layer 404 may be, but is not limited to, SOH.

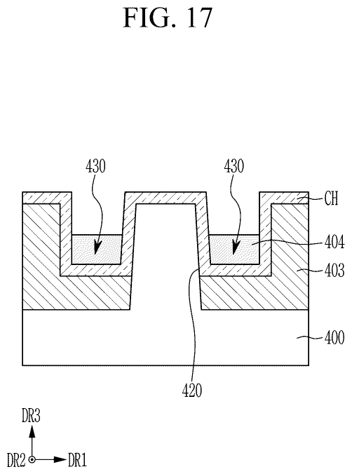

Next, referring to FIG. 17, the capping layer 404 is removed, leaving only a portion inside the recessed portions 430. Accordingly, as shown in FIG. 17, the capping layer 404 is positioned at the lower part of the recessed portions 430, and a portion of the channel layer CH may also be covered by the capping layer 404.

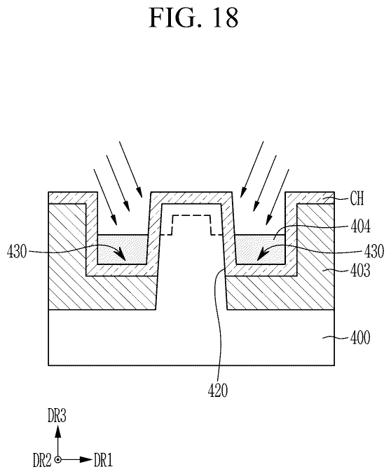

Next, referring to FIG. 18, the channel layer CH is doped. In example embodiments, the dopant may be an n-type dopant. For example, n-type impurities such as phosphorus, arsenic, bismuth, and antimony may be doped. In example embodiments, the channel layer CH covered by the capping layer 404 may not be doped. Therefore, the lower part of the recessed portions 430 may be limited to the channel region. In FIG. 18, the channel region is illustrated by a dotted line. As shown in FIG. 18, the channel layer CH not covered by the capping layer 404 and some regions of the pin 420 adjacent to the channel layer CH become doped regions. For example, the lower part of the recessed portions 430 is excluded from the channel region, and as the channel layer CH region is limited in this way, the Vth modulation may be prevented.

The subsequent manufacturing method is the same as shown in FIGS. 12 to 17. Detailed descriptions of the same components are omitted.

In addition, the structure of the amplifying transistor SF of the image sensor according to the present embodiment is not limited to the shape disclosed in FIGS. 5 and 6. The shape of the amplifying transistor SF may vary as long as the channel layer CH contains a two-dimensional material. Other embodiments are described below.

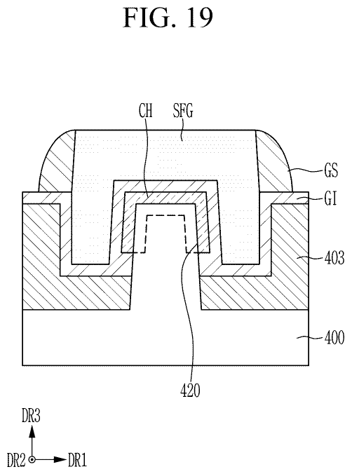

FIG. 19 illustrates the same region as FIG. 5 for another embodiment. Referring to FIG. 19, the amplifying transistor SF according to the present embodiment is the same as the embodiment of FIG. 5 except that the area occupied by the channel layer CH is narrower than that of FIG. 5. Detailed descriptions of the same components are omitted.

Referring to FIG. 19, the channel layer CH of the amplifying transistor SF according to the present embodiment does not cover a portion of the sidewall of the pin 420. In the embodiment of FIG. 5, the channel layer CH covers the entire sidewall of the pin 420, but in the embodiment of FIG. 19, the channel layer CH may cover only a portion of the sidewall of the pin 420. For example, a portion of the sidewall of the pin 420 may not be covered by the channel layer CH. In example embodiments, the channel region may be limited more than in FIG. 5. In FIG. 19, the channel region is illustrated by a dotted line. As shown in FIG. 19, the Vth modulation may be prevented as the channel region is limited.

Additionally, although the embodiments of FIGS. 5 and 19 illustrate a configuration in which the amplifying transistor SF includes the recessed portions 430 and the pin 420, in other embodiments, the amplifying transistor SF may be formed in a planar shape.

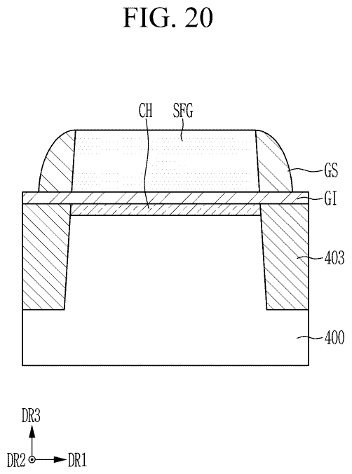

FIG. 20 illustrates the same region as FIG. 5 for another embodiment. Referring to FIG. 20, the display device according to the present embodiment may have a planar shape that does not include recessed portions where the amplifying transistor SF overlaps the gate electrode SFG. For example, referring to FIG. 20, the channel layer CH of the amplifying transistor SF according to the present embodiment is formed on the first substrate 400. The channel layer CH material may be the same as in other embodiments. For example, the channel layer CH may include or be a two-dimensional material. Detailed descriptions of the same components are omitted. The channel layer CH may be positioned planarly. The gate insulating film GI may also be positioned planarly on the channel layer CH. The gate electrode SFG may be positioned on the gate insulating film GI. The gate spacer GS may be positioned on both sides of the gate electrode SFG.

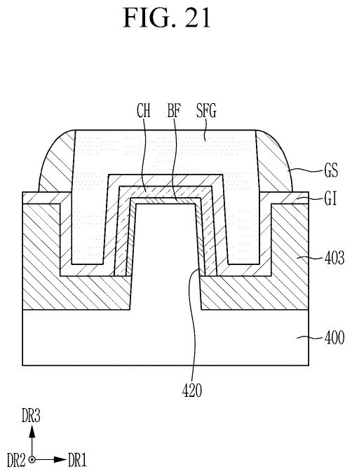

Additionally, an image sensor according to another embodiment may further include a buffer layer BF positioned between the channel layer CH and the pin 420. FIG. 21 illustrates the same region as FIG. 5 for another embodiment. Referring to FIG. 21, the image sensor according to the present embodiment further includes the buffer layer BF positioned between the channel layer CH and the pin 420.

The buffer layer BF may be, but is not limited to, silicon oxide. The buffer layer BF may improve the interface characteristics between the channel layer CH and the first substrate 400. Rather than forming the channel layer CH directly on the first substrate 400, the interface characteristics may be improved when forming the buffer layer BF and then forming the channel layer CH. Additionally, the buffer layer BF may function as a barrier layer during the channel layer CH doping process. Therefore, when the channel layer CH is doped, the pin 420 may be blocked from being doped, thus limiting the channel region to the channel layer CH shown in FIG. 21.

In the above, an embodiment in which the amplifying transistor SF is positioned in the first chip 1000 has been described. However, in another embodiment, the image sensor may include the first chip 1000, the second chip 2000, and the third chip 3000, and the amplifying transistor SF may be positioned in the second chip 2000.

FIG. 22 illustrates the same region as FIG. 5 for another embodiment. Referring to FIG. 22, the image sensor according to the present embodiment includes the first chip 1000, the second chip 2000, and the third chip 3000.

Most of the description of the first chip 1000 is the same as that described in FIG. 4 and is therefore omitted. Referring to FIG. 22, a transmission transistor TX is positioned on the first surface 400a of the first substrate 400, rather than an amplifying transistor. The transmission transistor TX may be electrically connected to the photoelectric conversion region 410. The transmission transistor TX may include a transmission gate TG and the floating diffusion FD positioned on an active pattern ACT. The transmission gate TG may include a first portion TGa positioned on the first surface 400a of the first substrate 400 and a second portion TGb extending from the first portion TGa into the first substrate 400. The maximum width of the first portion TGa in the second direction DR2 may be greater than the maximum width of the second portion TGb in the second direction DR2. The floating diffusion FD may be adjacent to one side of the transmission gate TG. The floating diffusion FD may have a second conductivity type (e.g., n-type) opposite to the first substrate 400.

The gate insulating film GI may be positioned between the transmission gate TG and the first substrate 400. The gate spacer GS may be positioned on the sidewall of the transmission gate TG. The gate spacer GS may include silicon nitride, silicon carbonitride or silicon oxynitride. A plurality of floating diffusions FD connected to different transmission transistors TX may be connected through the via VIA and the first wiring layer CL1.

Additionally, the first chip 1000 may further include a fourth insulating layer IL4. The first floating diffusion connection node FDCN_1 may be positioned within the fourth insulating layer IL4. The first floating diffusion connection node FDCN_1 may include a main connection portion FDCN_1A and a shielding portion FDCN_1B. The shielding portion FDCN_1B is positioned at the edge of the main connection portion FDCN_1A and may be positioned with a narrower area than the main connection portion FDCN_1A. The shielding portion FDCN_1B may prevent interference between floating diffusion connection nodes of neighboring pixels. The main connection portion FDCN_1A of the first floating diffusion connection node FDCN_1 is connected to the wirings of the first wiring layer CL1 and the second wiring layer CL2, but the shielding portion FDCN_1B of the first floating diffusion connection node FDCN_1 may not be connected to the wiring of the first wiring layer CL1 and the wiring of the second wiring layer CL2. Additionally, the main connection portion FDCN_1A of the first floating diffusion connection node FDCN_1 is positioned as an island separate from each pixel, but the shielding portion FDCN_1B may be positioned to be connected to a neighboring pixel. For example, the shielding portion FDCN_1B may be positioned as a linear shape extending in one direction on a plane. A separate voltage may be applied to the shielding portion FDCN_1B. However, this is an example, and the shielding portion FDCN_1B may be omitted depending on the embodiment.

As shown in FIG. 22, one surface of the first floating diffusion connection node FDCN_1 is exposed and not covered by the fourth insulating layer IL4. Accordingly, as will be described herein, one surface of the first floating diffusion connection node FDCN_1 may contact a second floating diffusion connection node FDCN_2 positioned in the second chip 2000.

The second chip 2000 is described below. The second chip 2000 may include a second substrate 500, a second wiring region 40, and a third wiring region 70.

The second substrate 500 may include a first surface 500a and a second surface 500b facing each other. The second wiring region 40 may be positioned on the first surface 500a of the second substrate 500, and the third wiring region 70 may be positioned on the second surface 500b of the second substrate 500.

The second substrate 500 may be a semiconductor substrate or a silicon on insulator (SOI) substrate. The semiconductor substrate may include, for example, a silicon substrate, a germanium substrate, or a silicon-germanium substrate. The second substrate 500 may include the first conductivity-type impurity. For example, the first conductivity-type impurity may include a p-type impurity such as at least one of aluminum (Al), boron (B), indium (In), or gallium (Ga).

The first surface 500a of the second substrate 500 may be positioned facing the first surface 400a of the first substrate 400.

The gate electrode RG of the reset transistor RX, the gate electrode DCG of the dual-conversion transistor DCX, the gate electrode SFG of the amplifying transistor SF, and the gate electrode AG of the selection transistor SEL described in FIG. 2 may be positioned on the first surface 500a of the second substrate 500. In FIG. 22, the reset transistor, the dual-conversion transistor, and the selection transistor are illustrated as transistors TR. The transistors TR have different shapes than the amplifying transistors SF and may contain different channel materials. The description of the shape of the amplifying transistor SF is omitted as it is the same as that described above. For example, the amplifying transistor SF may include the recessed portions 430 formed on the second substrate 500, the pin 420 positioned between the recessed portions 430, the channel layer CH positioned along the upper surface and side surface of the pin 420, the gate electrode SFG filling the recessed portions 430, the gate insulating film GI positioned between the gate electrode SFG and the channel layer CH, and the gate spacer GS positioned on both sides of the gate electrode SFG. The channel layer CH of the amplifying transistor SF may include or be a two-dimensional material. The description of the two-dimensional material is the same as that described above and is therefore omitted. However, the channel layers of the remaining transistors—i.e., the reset transistor, the dual-conversion transistor, and the selection transistor—may not contain two-dimensional materials.

The gate insulating film GI may be interposed between the gate electrodes of each of the reset transistor, dual-conversion transistor, and selection transistor and the second substrate 500. The gate spacer GS may be positioned on the sidewall of each of the gate electrodes. The gate spacer GS may include at least one of silicon nitride, silicon carbonitride or silicon oxynitride.

A fifth insulating layer IL5, a sixth insulating layer IL6, a seventh insulating layer IL7, a third wiring layer CL3, the plurality of vias VIA, and the second floating diffusion connection node FDCN_2 may be positioned on the first surface 500a of the second substrate 500.

The fifth insulating layer IL5, the sixth insulating layer IL6, and the seventh insulating layer IL7 may be a non-conductive material. For example, the fifth insulating layer IL5, the sixth insulating layer IL6, and the seventh insulating layer IL7 may be a silicon-based insulating material such as silicon oxide, silicon nitride, or silicon oxynitride.

The third wiring layer CL3, the via VIA, and the second floating diffusion connection node FDCN_2 may include metal materials. For example, the third wiring layer CL3, the via VIA, and the second floating diffusion connection node FDCN_2 may be copper (Cu).

The third wiring layer CL3 may be positioned within the sixth insulating layer IL6. The wiring of the third wiring layer CL3 and at least one of the gate electrode RG of the reset transistor RX, the gate electrode DCG of the dual-conversion transistor DCX, the gate electrode SFG of the amplifying transistor SF, and the gate electrode AG of the selection transistor SEL illustrated in FIG. 2 may be connected by the via VIA. Additionally, the third wiring layer CL3 and at least one of the electrodes of the reset transistor RX, the dual-conversion transistor DCX, the amplifying transistor SF, and the selection transistor SEL may be connected by the via VIA.

The second floating diffusion connection node FDCN_2 may be positioned within the seventh insulating layer IL7. The second floating diffusion connection node FDCN_2 may include a main connection portion FDCN_2A and a shielding portion FDCN_2B. The shielding portion FDCN_2B is positioned at the edge of the main connection portion FDCN_2A and may be positioned with a narrower area than the main connection portion FDCN_2A. The shielding portion FDCN_2B may prevent interference between floating diffusion connection nodes of neighboring pixels. The main connection portion FDCN_2A of the second floating diffusion connection node FDCN_2 is connected to the wiring of the third wiring layer CL3, but the shielding portion FDCN_2B of the second floating diffusion connection node FDCN_2 may not be connected to the wiring of the third wiring layer CL3. The main connection portion FDCN_2A of the second floating diffusion connection node FDCN_2 is positioned as an island separate from each pixel, but the shielding portion FDCN_2B may be positioned to be connected to a neighboring pixel. For example, the shielding portion FDCN_2B may be positioned as a linear shape extending in one direction on a plane. A separate voltage may be applied to the shielding portion FDCN_2B. However, this is an example, and the shielding portion FDCN_2B may be omitted depending on the embodiment.

As shown in FIG. 22, one surface of the second floating diffusion connection node FDCN_2 is exposed and not covered by the seventh insulating layer IL7. Accordingly, as shown in FIG. 4, the first floating diffusion connection node FDCN_1 positioned in the first chip 1000 and the second floating diffusion connection node FDCN_2 positioned in the second chip 2000 may be in contact with each other.

Referring to FIG. 22, the second chip 2000 may include a deep node DN penetrating the second substrate 500. The deep node DN may contain a metal—for example, copper (Cu). However, the above material is only an example and other metallic materials may also be included.

The deep node DN is positioned to penetrate the second substrate 500, and one end of the deep node DN may be positioned on the first surface 500a and the other end may be positioned on the second surface 500b. Throughout this specification, the expression “positioned on” a certain surface is not limited to being positioned in contact with the surface, but also includes being positioned in a form that does not contact the surface or in a protruding form. For example, as shown in FIG. 22, one end of the deep node DN may be positioned so as to protrude from the first surface 500a, and the other end may be positioned so as to protrude from the second surface 500b.

Therefore, as shown in FIG. 22, one end of the deep node DN may be in contact with the wiring of the third wiring layer CL3. Additionally, the other end of the deep node DN may be in contact with a fourth wiring layer CL4 positioned on the second surface 500b of the second substrate 500.

An eighth insulating layer IL8, a ninth insulating layer IL9, a tenth insulating layer IL10, the fourth wiring layer CL4, a fifth wiring layer CL5, and the via VIA may be positioned on the second surface 500b of the second substrate 500.

The eighth insulating layer IL8, the ninth insulating layer IL9, and the tenth insulating layer IL10 may be a non-conductive material. For example, the eighth insulating layer IL8, the ninth insulating layer IL9, and the tenth insulating layer IL10 may be a silicon-based insulating material such as silicon oxide, silicon nitride, or silicon oxynitride.

The fourth wiring layer CL4, the fifth wiring layer CL5, and the via VIA may be a metal material. For example, the fourth wiring layer CL4, the fifth wiring layer CL5, and the via VIA may be copper Cu. However, these materials are only examples and the present disclosure is not limited thereto.

The fourth wiring layer CL4 may be positioned within the ninth insulating layer IL9. The fifth wiring layer CL5 may be positioned within the tenth insulating layer IL10. The fourth wiring layer CL4 and the fifth wiring layer CL5 may be connected through the via VIA.

The deep node DN may be positioned in the fifth insulating layer IL5, the second substrate 500, and the eighth insulating layer IL8. The deep node DN is positioned to penetrate the second substrate 500 and may connect one or more of the reset transistor RX, the dual-conversion transistor DCX, the amplifying transistor SF, and the selection transistor SEL, which are positioned on the first surface 500a of the second substrate 500, and the fourth wiring layer CL4 and the fifth wiring layer CL5 positioned on the second surface 500b of the second substrate 500.

For example, the wiring positioned in the fourth wiring layer CL4 and the fifth wiring layer CL5 may be connected to the gate electrode RG of the reset transistor RX, the gate electrode DCG of the dual-conversion transistor DCX, and the gate electrode AG of the selection transistor SEL to transmit a gate signal. Additionally, the wiring positioned in the fourth wiring layer CL4 and the fifth wiring layer CL5 may be connected to the source electrodes of the reset transistor RX and the amplifying transistor SF to apply the power supply voltage (Vpix). Additionally, the output wiring Vout positioned in the fourth wiring layer CL4 or the fifth wiring layer CL5 may be connected to the drain electrode of the selection transistor SEL. However, depending on the embodiment, the deep node DN may be omitted. In example embodiments, the wiring connected to the transistor positioned on the second substrate 500 may be positioned on the first surface 500a of the second substrate 500.

In addition, referring to FIG. 22, the second chip 2000 may be connected to the third chip 3000. The third chip 3000 may include a third substrate 700 and a fourth wiring region 80. A transistor (not shown) forming a logic circuit may be positioned on a first surface 700a of the third substrate 700, and a plurality of wirings LCL may be positioned in the fourth wiring region 80. The fourth wiring region 80 includes an insulating film LIL, and the plurality of wirings LCL may be connected to the wiring of the second chip 2000 through a via (not shown).

The third substrate 700 may be a semiconductor substrate or a silicon on insulator (SOI) substrate. The semiconductor substrate may include, for example, a silicon substrate, a germanium substrate, or a silicon-germanium substrate. The third substrate 700 may include the first conductivity-type impurity. For example, the first conductivity-type impurity may include a p-type impurity such as at least one of aluminum (Al), boron (B), indium (In), or gallium (Ga).

In addition, in FIG. 22, an embodiment is illustrated in which the first surface 400a of the first substrate 400 and the first surface 500a of the second substrate 500 face each other, but in another embodiment, the first surface 400a of the first substrate 400 and the second surface 500b of the second substrate 500 may face each other.

FIG. 23 illustrates the same region as FIG. 22 for another embodiment. Referring to FIG. 23, the first surface 400a of the first substrate 400 and the second surface 500b of the second substrate 500 may be positioned facing each other. As shown in FIG. 23, the reset transistor RX, the dual-conversion transistor DCX, the amplifying transistor SF, and the selection transistor SEL are positioned on the first surface 500a of the second substrate 500, and the floating diffusion FD of the first chip 1000 may be connected through the deep node DN penetrating the second substrate 500.

Referring to FIG. 23, the descriptions of the first chip 1000 and the third chip 3000 are the same as described above. Detailed descriptions of the same components are omitted.

In FIG. 23, the fourth insulating layer IL4 may be positioned on the second surface 500b of the second substrate 500. Additionally, the fifth insulating layer IL5 and the sixth insulating layer IL6 may be positioned on the first surface 500a of the second substrate 500. Vias VIA may be positioned in the fifth insulating layer IL5, and the vias VIA may be connected to each transistor. Additionally, the third wiring layer CL3 may be positioned in the sixth insulating layer IL6. The third wiring layer CL3 may be connected to each transistor and a first pad P1 through the via VIA. A second pad P2 is positioned on the third chip 3000, and the first pad P1 and the second pad P2 may be in contact. The first pad P1 and the second pad P2 may include, but are not limited to, copper.

However, the structure described above is an example and the present disclosure is not limited thereto. The image sensor according to the present embodiment is not limited to the structure illustrated in FIGS. 22 and 23 if a transmission transistor is positioned in the first chip 1000, the reset transistor RX, the dual-conversion transistor DCX, the amplifying transistor SF, and the selection transistor SEL are positioned in the second chip 2000, and the channel layer of the amplifying transistor SF has a structure including a two-dimensional material. In example embodiments, among the plurality of transistors positioned in the second chip 2000, only the amplifying transistor SF may have a channel that includes a two-dimensional material, and the channels of other transistors may not include a two-dimensional material. For example, the channel materials of the transistors positioned in the second chip 2000 may be different from each other. As such, the noise generated by the image sensor may be improved by including a two-dimensional material in the channel material of the amplifying transistor SF.

While this disclosure has been described in connection with what is presently considered to be practical embodiments, it should be understood that the disclosure is not limited to the disclosed embodiments, but, on the contrary, is intended to cover various modifications and equivalent arrangements included within the spirit and scope of the appended claims.

### DESCRIPTION OF SYMBOLS

420: Pin 430: Recessed portion
SF: Amplifying transistor CH: Channel layer
PD: Photodiode 410: Photoelectric conversion region
400: First substrate 500: Second substrate

What is claimed is:

1. An image sensor, comprising:
a substrate;
a selection transistor on a surface of the substrate; and
an amplifying transistor connected to the selection transistor,
wherein a channel material of the selection transistor and a channel material of the amplifying transistor are different materials, and
the channel material of the amplifying transistor comprises a two-dimensional material.

2. The image sensor of claim 1, wherein
the two-dimensional material comprises a metal dichalcogenide represented by MX₂,
wherein M is a transition metal, and
X is sulfur, selenium or tellurium.

3. The image sensor of claim 1, wherein
the two-dimensional material comprises at least one material selected from the group consisting of molybdenum disulfide (MoS₂), molybdenum diselenide (MoSe₂), tungsten disulfide (WS₂), tungsten diselenide (WSe₂), and black phosphorus (BP).

4. The image sensor of claim 1, wherein
the amplifying transistor comprises;
a channel layer positioned on a side surface and an upper surface of a pin positioned between two recessed portions of the substrate; and
a gate electrode positioned to overlap the recessed portions of the substrate and the pin.

5. The image sensor of claim 4, wherein
a width of the pin positioned between the two recessed portions of the substrate is 10 nm to 50 nm in a first direction.

6. The image sensor of claim 4, wherein
a thickness of the channel layer is 1 nm to 10 nm in a first direction.

7. The image sensor of claim 4, wherein
a lowermost part of the gate electrode does not overlap the channel layer in a direction perpendicular to the substrate.

8. The image sensor of claim 4, wherein
a portion of the side surface of the pin is not covered by the channel layer.

9. The image sensor of claim 4, further comprising
a buffer layer positioned between the channel layer and the pin of the substrate.

10. The image sensor of claim 1, wherein
the amplifying transistor comprises a channel layer positioned on an upper surface of the substrate;
a gate insulating film positioned on the channel layer; and
a gate electrode positioned on the gate insulating film, to overlap the channel layer.

11. An image sensor, comprising:
a first substrate including a first surface of the first substrate and a second surface of the first substrate facing the first surface of the first substrate, and including a photoelectric conversion region;
a transmission transistor and a floating diffusion positioned on the first surface of the first substrate;
a second substrate including a first surface of the second substrate and a second surface of the second substrate facing the first surface of the second substrate; and
a plurality of transistors positioned on the first surface of the second substrate, each transistor of the plurality of transistors being connected to the transmission transistor,
wherein the plurality of transistors positioned on the first surface of the second substrate comprises
a reset transistor configured to initialize the floating diffusion;
an amplifying transistor having a gate connected to the floating diffusion; and
a selection transistor connected to an end of the amplifying transistor, and
wherein a channel material of the amplifying transistor is different from a channel material of the reset transistor and a channel material of the selection transistor.

12. The image sensor of claim 11, wherein
the channel material of the amplifying transistor comprises a two-dimensional material.

13. The image sensor of claim 12, wherein
the channel material of the reset transistor and the channel material of the selection transistor comprise doped silicon.

14. The image sensor of claim 11, wherein
the amplifying transistor comprises;
a channel layer positioned on a side surface and an upper surface of a pin positioned between two recessed portions of the second substrate; and
a gate electrode positioned to overlap the recessed portions of the substrate and the pin.

15. The image sensor of claim 14, wherein
a lowermost part of the gate electrode does not overlap the channel layer in a direction perpendicular to the first substrate.

16. The image sensor of claim 11, wherein
the first surface of the first substrate and the first surface of the second substrate face each other.

17. The image sensor of claim 11, wherein
the first surface of the first substrate and the second surface of the second substrate face each other.

18. An image sensor, comprising:
a substrate including a photoelectric conversion region;
a transmission transistor connected to the photoelectric conversion region;
a floating diffusion connected to the transmission transistor;
an amplifying transistor having a gate connected to the floating diffusion;
a reset transistor configured to initialize the floating diffusion; and
a selection transistor connected to one end of the amplifying transistor,
wherein a channel material of the amplifying transistor is different from a channel material of the reset transistor and a channel material of the selection transistor, and
wherein the channel material of the amplifying transistor includes a two-dimensional material.

19. The image sensor of claim 18, wherein
the channel material of the transmission transistor, the channel material of the reset transistor, and the channel material of the selection transistor, each comprise doped silicon.

20. The image sensor of claim 18,
wherein the amplifying transistor comprises:
a channel layer positioned on a side surface and an upper surface of a pin positioned between two recessed portions of the substrate; and
a gate electrode positioned to overlap the recessed portions of the substrate and the pin, and
wherein a lowermost part of the gate electrode does not overlap the channel layer in a direction perpendicular to the substrate.
